(19) United States
(12) Patent Application Publication
(10) Pub. No.: US 2020/0328066 A1
(43) Pub. Date: Oct. 15, 2020

(54) PLASMA DENSIFICATION WITHIN A PROCESSING CHAMBER

(71) Applicant: Applied Materials, Inc., Santa Clara, CA (US)

(72) Inventors: Byung Seok KWON, San Jose, CA (US); Dong Hyung LEE, Danville, CA (US); Prashant Kumar KULSHRESHTHA, San Jose, CA (US); Kwangduk Douglas LEE, Redwood City, CA (US); Ratsamee LIMDULPAIBOON, San Jose, CA (US); Irfan JAMIL, Danville, CA (US); Pyeong Youn ROH, San Ramon, CA (US); Jun MA, San Diego, CA (US); Amit Kumar BANSAL, Milpitas, CA (US); Tuan Anh NGUYEN, San Jose, CA (US); Juan Carlos ROCHA-ALVAREZ, San Carlos, CA (US)

(21) Appl. No.: 16/829,573

(22) Filed: Mar. 25, 2020

Related U.S. Application Data
(60) Provisional application No. 62/832,571, filed on Apr. 11, 2019.

(51) Int. Cl. H01J 37/32; C23C 16/50; C23C 16/44; C23C 16/455

(52) U.S. Cl. CPC H01J 37/32449; C23C 16/50; C23C 16/4412; C23C 16/545; C23C 16/45536; C23C 16/45595; C23C 16/4404

(57) ABSTRACT

A system and method for forming a film includes generating a plasma in a processing volume of a processing chamber to form the film on a substrate. The processing chamber may include a gas distributor configured to generate the plasma in the processing volume. Further, a barrier gas is provided into the processing volume to form a gas curtain around a plasma located in the processing volume. The barrier gas is supplied by a gas supply source through an inlet port disposed along a first side of the processing chamber. Further, an exhaust port is disposed along the first side of the processing chamber and the plasma and the barrier gas is purged via the exhaust port.

### CROSS-REFERENCE TO RELATED APPLICATIONS

This application claims priority to U.S. Provisional Patent Application 62/832,571, filed on Apr. 11, 2019, the disclosure of which is incorporated herein by reference in its entirety.

### BACKGROUND

### Field

The embodiments of the disclosure generally relate to the deposition of thin films on semiconductor substrates.

### Description of the Related Art

Plasma-enhanced chemical vapor deposition (PECVD) can be used to form one or more films on a substrate for semiconductor device fabrication. In many instances, while performing PECVD, plasma is generated within a processing chamber to form the film or films on the substrate. Further, the uniformity of one or more parameters of the films corresponds to the uniformity of the density of the plasma. Accordingly, any differences in the plasma density may cause a variation in one or more parameters of the film or films. In one instance, a non-uniform plasma density may generate a film having a non-uniform edge-to-edge thickness, which may cause the processed substrate to be unsuitable for use in semiconductor device fabrication. Accordingly, production yields may be reduced and manufacturing costs may be increased.

Thus, there remains a need in the art for an improved method of forming thin films on semiconductor substrates and hardware components.

### SUMMARY

In one embodiment, a method for forming a film comprises generating a plasma in a processing volume of a processing chamber to form the film on a substrate, introducing, via an inlet port from a first side of the processing chamber, a barrier gas into the processing volume of the processing chamber to generate a gas curtain along one or more edges of the substrate, and purging, via an exhaust port along a first side of the processing chamber, the plasma and the barrier gas.

In one embodiment, a processing chamber comprises a substrate support configured to support a substrate within a processing volume the processing chamber, a gas inlet port disposed along a first side of the processing chamber, and an exhaust port disposed along the first side of the processing chamber. The gas inlet port is configured to be coupled to a gas supply source configured to introduce a barrier gas into the processing volume of the processing chamber to generate a gas curtain along one or more edges of the substrate.

In one embodiment, a processing chamber comprises a gas distributor, a substrate support, a gas inlet, a gas supply source, and an exhaust port. The gas distributor is configured to generate a plasma within a processing volume of the processing chamber by ionizing a processing gas. The substrate support is configured to support a substrate within a processing volume the processing chamber. The gas inlet port is disposed along a first side of the processing chamber. The gas supply source is coupled to the gas inlet port and is configured to introduce a barrier gas into the processing volume of the processing chamber to generate a gas curtain along one or more edges of the substrate. The exhaust port is disposed along the first side of the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1 and 2 are schematic cross-sectional views of a substrate processing system, according to one or more embodiments.

FIG. 3 illustrates a top view of a substrate and a gas curtain, according to one or more embodiments.

FIG. 4 illustrates a flow chart of a method of forming a film, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Semiconductor devices can be generated by forming one or more films on a substrate and can include silicon-, nitride-, and oxide-containing films, among others. Processing chambers for processing substrates can be configured to perform operations including chemical vapor deposition (CVD) including plasma-enhanced CVD (PECVD), plasma-enhanced atomic layer deposition (PEALD), or physical vapor deposition (PVD). The quality of the films on the substrates can be negatively impacted based on the difference, or non-uniformity, in plasma density of a plasma over a substrate within a processing chamber. The difference in the plasma density within the processing volume of the processing chamber may negatively affect the edge-to-edge uniformity of the films formed on a substrate. Further, any non-uniformity of the films may result in a drop in production yield, increasing the manufacturing costs of semiconductor devices.

Using the systems and methods discussed herein, the uniformity of the density of the plasma within the processing volume, in particular over the substrate, may be improved significantly. Uniformity may be improved for a particular process, for example, by introducing a barrier gas into the processing volume to generate a gas curtain that decreases the dispersion of the plasma within the processing volume. The decreased dispersion of the plasma within the processing volumes increases the uniformity of the plasma over the substrate. In various embodiments, decreased dispersion of the plasma within the processing volume (e.g., increased densification of the plasma within the processing volume) increases the deposition rate by about 20 percent as compared to processing systems that do not include techniques to decrease dispersion of the plasma. Further, decreasing the dispersion of the plasma may positively adjust film properties such as the refractive index (n), stress, and extinction coefficient (k), due, in part, to the increased deposition uniformity of formed film.

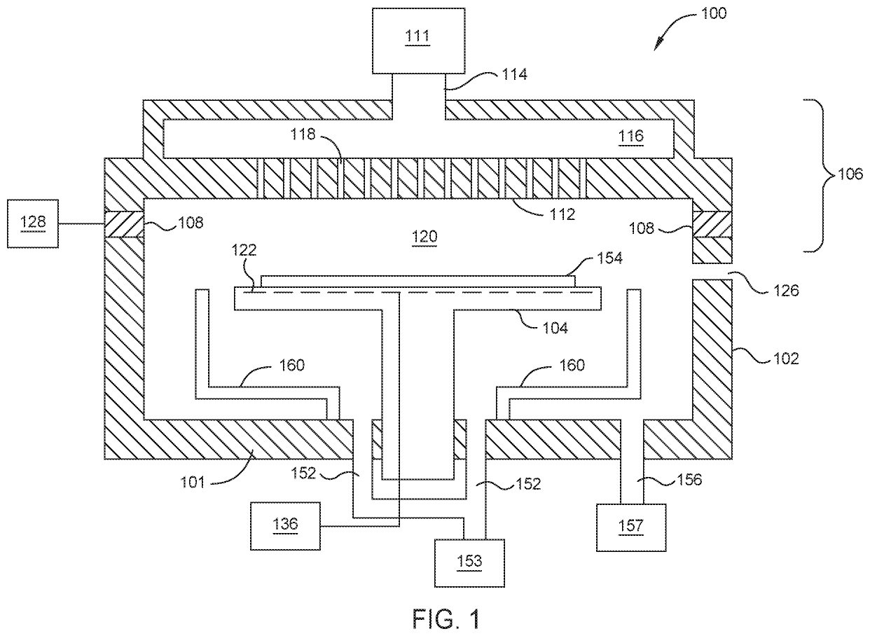

FIG. 1 illustrates a schematic cross-sectional view of a processing chamber 100 according to one implementation described herein. The processing chamber 100 is a PECVD chamber, but may also be another plasma enhanced processing chamber. The processing chamber 100 features a chamber body 102, a substrate support 104 disposed inside the chamber body 102, and a lid assembly 106 coupled to the chamber body 102 and enclosing the substrate support 104 in a processing volume 120. The substrate support 104 is configured to support a substrate 154 thereon during processing. The substrate 154 is provided to the processing volume 120 through an opening 126. While the embodiment of FIG. 1 is directed to a PECVD chamber, the lid assembly 106 and substrate support 104 of FIG. 1 may be used with other processing chamber that utilize plasma generated in the processing volume 120.

The gas supply source 111 includes one or more gas sources. The gas supply source 111 is configured to deliver the one or more gases from the one or more gas sources to the processing volume 120. Each of the one or more gas sources provides a processing gas (such as argon, hydrogen or helium) that may be ionized to for plasma formation. For example, one or more of a carrier gas and an ionizable gas may be provided into the processing volume 120 along with one or more precursors. When processing a 300 mm substrate, the processing gases are introduced to the processing chamber 100 at a flow rate from about 6500 sccm to about 8000 sccm, from about 100 sccm to about 10,000 sccm, or from about 100 sccm to about 1000 sccm. Alternatively, other flow rates may be utilized. In some examples, a remote plasma source can be used to deliver plasma to the processing chamber 100 and can be coupled to the gas supply source 111.

The gas distributor 112 features openings 118 for admitting a processing gas or gases into the processing volume 120 from the gas supply source 111. The processing gases are supplied to the processing chamber 100 via the conduit 114, and the process gases enter a gas mixing region 116 prior to flowing through the openings 118.

An electrode 108 is disposed adjacent to the chamber body 102 and separates the chamber body 102 from other components of the lid assembly 106. The electrode 108 is part of the lid assembly 106, but may be a separate side wall electrode. The electrode 108 may be an annular, or ring-like member, and may be a ring electrode. The electrode 108 may be a continuous loop around a circumference of the processing chamber 100 surrounding the processing volume 120, or may be discontinuous at selected locations. The electrode 108 may also be a perforated electrode, such as a perforated ring or a mesh electrode. The electrode 108 may also be a plate electrode, for example, a secondary gas distributor.

The electrode 108 is coupled to a power source 128. The power source 128 is a radio frequency (RF) power source that is electrically coupled to the electrode 108. Further, the power source 128 provides between about 100 Watts and about 3,000 Watts at a frequency of about 50 kHz to about 13.6 MHZ. Optionally, the power source 128 can be pulsed during various operations. The electrode 108 and power source 128 facilitate additional control of a plasma formed within the processing volume 120.

The substrate support 104 contains or is formed from one or more metallic or ceramic materials. Exemplary metallic or ceramic materials include one or more metals, metal oxides, metal nitrides, metal oxynitrides, or any combination thereof. For example, the substrate support 104 may contain or be formed from aluminum, aluminum oxide, aluminum nitride, aluminum oxynitride, or any combination thereof.

An electrode 122 is embedded within the substrate support 104, but may alternatively be coupled to a surface of the substrate support 104. The electrode 122 is coupled to a power source 136. The power source 136 is DC power, pulsed DC power, radio frequency (RF) power, pulsed RF power, or any combination thereof. The power source 136 is configured to drive the electrode 122 with a drive signal to generate a plasma within the processing volume 120. The drive signal may be one of a DC signal and a varying voltage signal (e.g., RF signal). Further, the electrode 122 may alternatively be coupled to the power source 128 instead of the power source 136, and the power source 136 may be omitted.

Plasma is generated in the processing volume 120 via the power source 128 and the power source 136. An RF field is created by driving at least one of the electrode 108 and driving the electrode 122 with drive signals to facilitate the formation of a capacitive plasma within the processing volume 120. The presence of a plasma facilitates processing of the substrate 154, for example, deposition of a film onto a surface of the substrate 154.

One or more gas inlet ports 152 are coupled to gas supply source 153 and disposed within a bottom chamber wall 101 of the processing chamber 100 beneath the substrate support 104. The gas supply source 153 provides one or more gases through the gas inlet port 152 and into the processing volume 120. For example, the gas supply source 153 provides a barrier gas into the processing volume 120. The barrier gas is any gas that does not significantly interact (e.g., mix) with the plasma and is able to create a gas curtain around the substrate 154, slowing the dispersion of the plasma within the processing volume 120. For example, a gas that does not significantly interact with the plasma may be any gas that at least partially slows the dispersion of the plasma within the processing volume 120. Further, a barrier gas may be any gas that reduces the formation of parasitic plasma. Additionally, the barrier gas may be an inert gas. Alternatively, or additionally, the barrier gas may be any one of helium, hydrogen, nitrogen, argon, oxygen, or nitrogen oxide (NOₓ), among others. The gas supply source 153 controls the type of barrier gas and the flow rate of the barrier gas into the processing volume 120, controlling one or more parameters of the gas curtain created by the barrier gas. Additionally, the barrier gas may function as a purge gas to facilitate removal of gases, plasma, or processing by-products from the processing volume 120.

The shield (or ring) 160 directs the barrier gas to flow along the perimeter of the substrate support 104 and the perimeter of the substrate 154. For example, the shield 160 may control the flow of the barrier gas such that the barrier gas flows along the perimeter of the substrate support 104 and the perimeter of the substrate 154 before dispersing within the processing volume 120. The shield 160 is coupled to the chamber wall 101. Alternatively, the shield 160 may be coupled to another chamber wall of the processing chamber 100. As illustrated, the shield 160 circumscribes the substrate support 104.

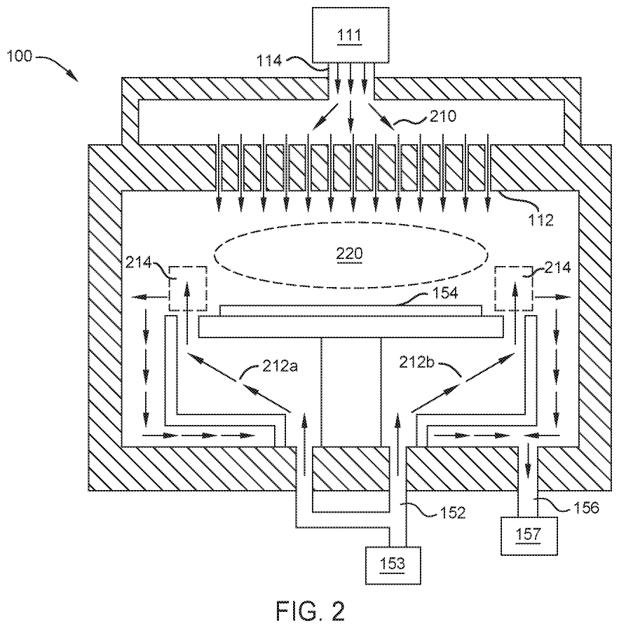

An exhaust port 156 is coupled to a vacuum pump 157 and is disposed along the same wall, e.g. chamber wall 101, of the processing chamber 100 as is the gas inlet port 152. Alternatively, the exhaust port 156 may positioned along another wall of the processing chamber 100 as long as the flow of the barrier gas along the perimeter of the substrate 154 is not negatively affected, preventing the gas curtain 214 of FIG. 2 from being formed. The vacuum pump 157 removes excess process gases or by-products from the processing volume 120 during and/or after processing via the exhaust port 156.

FIG. 2 illustrates a schematic cross-sectional view of the processing chamber 100, as well as how gases flow within the processing chamber 100 and the creation of a gas curtain within the processing chamber 100, according to one or more embodiments. One or more processing gases flow along path 210 from the gas supply source 111 and through the gas distributor 112 to facilitate processing of the substrate 154. The processing gases are converted into a plasma within a plasma region 220 over the substrate 154 within the processing volume 120 of FIG. 1. A barrier gas is provided via the gas inlet port 152 to function as a purge gas, aiding in the removal of excess processing gases or by-products from the processing volume 120 during and/or after processing via the exhaust port 156 and to also generate a gas curtain 214. The barrier gas flows along path 212 (e.g., the paths 212a and 212b). As the barrier gas reduces the dispersion of the plasma throughout the processing chamber is achieved. For example, the barrier gas may not interact (e.g., mix) due to a difference in electronegativity between the barrier gas and the processing gases. Further, reducing the dispersion of the plasma throughout the processing chamber, increases the uniformity of the density of the plasma within the plasma region 220 over the substrate. For example, the density of the plasma along the edge of the substrate 154 may be similar to the density of the plasma near the center of the substrate 154. Further, a film formed from the plasma having a more uniform density may have a more uniform edge- to edge thickness or k value. For example, the thickness of the film and/or the k value of the film along the edge of the substrate 154 may be similar to the thickness of the film and/or k value of the film near the center of the substrate 154. Additionally, the deposition rate of a film formed from a plasma having a more uniform density may be about 20 percent higher than a deposition rate of a film formed form a plasma not having a uniform density, while maintaining a similar film quality.

The gas curtain 214 functions as a choke to reduce dispersion of the plasma within the processing volume 120, densifying the plasma within plasma region 220 and increasing the uniformity of the density of the plasma within the plasma region 220. Further, the gas curtain may be created around the entire perimeter of the substrate 154. Decreasing the dispersion of the plasma within the processing volume entraps the plasma and increases the uniformity of the plasma within plasma region 220. Accordingly, the deposition uniformity of a corresponding film is increased. Further, decreasing the dispersion of the plasma increases the quality of the plasma by increasing the rate of deposition and/or the k value of the film formed on the substrate. Additionally, the cross-sectional shape of the edge-to-edge thickness profile of a film formed on a substrate within a processing chamber employing a barrier gas is flatter than the cross-sectional shape of the edge-to-edge thickness profile of a film formed on a substrate within a processing chamber not employing a barrier gas. Further, the k value profile of a film formed on a substrate within a processing chamber employing a barrier gas is greater than the k value profile of a film formed on a substrate within a processing chamber not employing a barrier gas.

The flow rate and type of the barrier gas may correspond to the amount at which the plasma is prevented from being dispersed within the processing volume 120, and to the uniformity of the plasma density. For example, higher flow rates may provide a larger decrease in the amount that the plasma is dispersed and larger increases to the uniformity of the plasma density as compared to lower flow rates. The flow rate of the barrier gas may be in a range of about 100 sccm to about 5000 sccm. In one example embodiment, the flow rate of the barrier gas may be in a rage of about 100 sccm to about 1000 sccm when the flow rate of a processing gas is about 3 liters, depending on the type of processing gas utilized. Further, the flow rate of the barrier gas may be less than of the flow rate of the processing gas. For example, the flow rate of the barrier gas may be a percentage of the flow rate of the processing gas. An example flow rate of the barrier gas may be in a range of about 10% to about 80% of the processing gas. Alternatively, percentages of less than 10% and greater than 80% may be utilized.

Further, different types of barrier gas may prevent different amounts of plasma from being dispersed and provide larger increases to the uniformity of the plasma density within the processing volume 120. Further, the flow rate of the barrier gas may be based on at least one of the type of barrier gas utilized, the type of gas used to generate the plasma, the flow rate of the processing gas, and the amount of plasma dispersion to be prevented. For example, the flow rate of a first barrier gas utilized for a first processing gas may differ from the flow rate of the first barrier gas utilized for a second processing gas. Further, the flow rate of a first barrier gas utilized for a first processing gas may differ from the flow rate of a second barrier gas utilized for the first processing gas. The type of barrier gas may be selected based on an electronegativity of the processing gas or gases. For example, the barrier gas may be selected based on a difference in electronegativity between the processing gas and the barrier gas. Additionally the barrier gas may be selected to maximize a difference in electronegativity between the processing gas and the barrier gas. Further, the barrier gas may be selected according to the drive signal utilized to convert the processing gas into a plasma. For example, the barrier gas may be selected such that the barrier gas does not ionize (e.g., ignite) into a plasma in the presence of the drive signal utilized to convert the processing gas into a plasma.

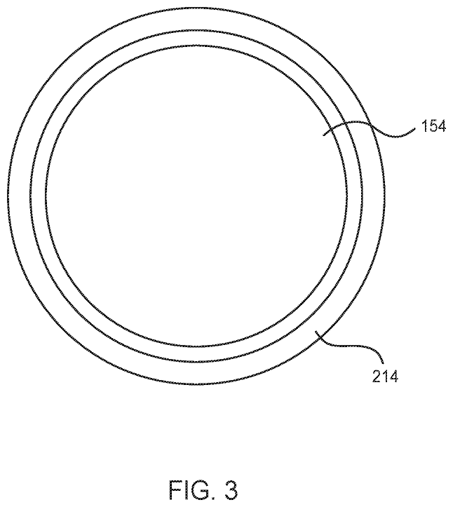

FIG. 3 illustrates a top view of the gas curtain 214, according to one or more embodiments. As illustrated by FIG. 3, the substrate 154 is surrounded by the gas curtain 214. Alternatively, the gas curtain 214 may partially surround the substrate 154. Further, the thickness of the gas curtain 214 may be substantially uniform, or non-uniform. Additionally, or alternatively, the distance between the substrate 154 and the gas curtain 214 may be substantially uniform or non-uniform.

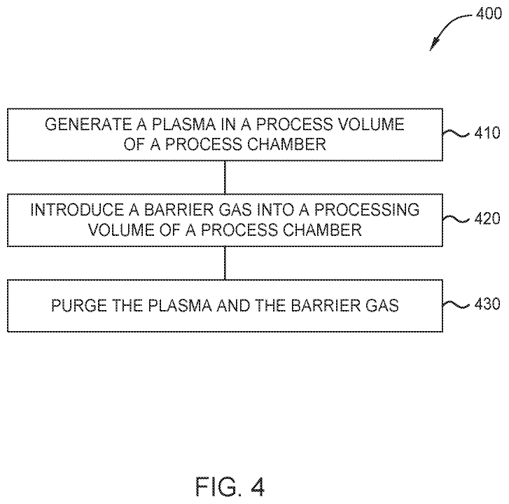

As discussed herein, film deposition operations can include the formation of one or more films on the substrate 154 positioned on the substrate support 104. FIG. 4 is a flow chart of a method 400 for processing a substrate, according to one or more embodiments. The method 400 may be employed to form one or more films on the substrate 154. For example, the substrate 154 may be positioned within the processing chamber 100 to form the one or more films on the substrate 154.

At operation 410 a plasma in generated in the processing volume 120 of the processing chamber 100. For example, one or more process gases may be introduced by the gas supply source 111 to the processing chamber 100. The process gases may include at least one precursor gas, ionizable gas and carrier gas, and one or more of the processing gases may be ionized to form a plasma. For example, the electrode 122 may be driven with an RF signal by the power source 136 to ionize the processing gas or gases into a plasma. Further, the precursor gas may be utilized to form a film on a substrate in the presence of the plasma. For example, the power sources 128 and 136 may be driven while the process gas is introduced into the processing chamber 100 to generate the plasma.

At operation 420 a barrier gas is introduced into the processing volume 120 of the processing chamber 100. For example, the barrier gas may be introduced into processing volume 120 of the processing chamber 100 by the gas supply source 153 via the gas inlet port 152. The barrier gas may generate a gas curtain, e.g., gas curtain 214, which reduces the dispersion of the plasma within the processing volume 120, increasing the uniformity of the density of the plasma over the substrate 154. For example, the gas curtain 214 may function as a choke, reducing the amount of parasitic plasma that is formed near the edge of the substrate 154 and increasing uniformity of the density of the plasma within the plasma region 220. Accordingly, the edge-to-edge uniformity of one or more parameters of a film formed on the substrate 154 is also increased. For example, the edge-to-edge uniformity of a thickness of the film may be increased. Alternatively, or additionally, the edge-to-edge uniformity of a k value of the film may be increased. Further, the increase in the uniformity of the density may generate localized plasma densification which may enhance the plasma quality and increase the deposition rate of a corresponding film, improving one or more parameters of the film.

The flow rate of the of the barrier gas may be selected depending on the type of processing gas, the type of barrier gas, and/or the flow rate of the processing gas. The flow rate of the barrier gas may be less than the flow rate of the processing gas. Further, the flow rate of the barrier gas may be a percentage of the flow rate of the processing gas. Additionally, or alternatively, the flow rate of the barrier gas may correspond to the amount at which the plasma is densified over the substrate 154. For example, the flow rate of the barrier gas may be adjusted to maintain a substantially uniform plasma density over the substrate 154. For example, the flow rate of the barrier gas may be adjusted to maintain a plasma density that is within about 5% of optimum uniformity. Further, the flow rate of the barrier gas may be increased when the uniformity of plasma density is less than a first threshold value and increased when the plasma density is greater than a second threshold value. While two thresholds are discussed, alternatively, more than two thresholds or less than two thresholds may be utilized.

At operation 430 the plasma and barrier gas is purged from the processing chamber 100. For example, the exhaust port 156 may be coupled to the vacuum pump 157, and the vacuum pump 157 removes excess process gases or by-products from the processing volume 120 during and/or after processing via the exhaust.

As such, using the systems and methods discussed herein, through the introduction of a barrier gas, the uniformity of the density of a plasma may be increased within a processing volume of a processing chamber, increasing the uniformity of a corresponding film or films generated on a substrate. Further, the disposition rate of films is increased. As such, the production yield of corresponding semiconductor devices may be increased and the manufacturing costs may be decreased. The barrier gas may generate a gas curtain, or choke, to decrease the dispersion of the plasma within the processing volume, increasing the uniformity of the density of the plasma over the substrate.

While the foregoing is directed to embodiments of the present disclosure, other and further embodiments of the disclosure may be devised without departing from the basic scope thereof, and the scope thereof is determined by the claims that follow.

What is claimed is:

1. A method for forming a film, the method comprising:
generating a plasma in a processing volume of a processing chamber to form the film on a substrate;
introducing, via an inlet port from a first side of the processing chamber, a barrier gas into the processing volume of the processing chamber to generate a gas curtain along one or more edges of the substrate during a period overlapping with generating a plasma in the processing volume; and
purging, via an exhaust port of the processing chamber, the plasma and the barrier gas.

2. The method of claim 1, wherein generating the plasma comprises ionizing a processing gas flowing through a gas distributor of the processing chamber.

3. The method of claim 2, wherein the substrate is disposed on a substrate support of the processing chamber, and wherein the substrate is positioned between the gas distributor and the first side.

4. The method of claim 2, wherein a flow rate of the barrier gas is based on at least one of a flow rate of the processing gas, a type of the barrier gas, and a type of the processing gas.

5. The method of claim 1, wherein the barrier gas is one of helium, hydrogen, nitrogen, argon, oxygen, or nitrogen oxide.

6. The method of claim 1, wherein the barrier gas is an inert gas.

7. The method of claim 1, wherein generating the gas curtain along the one or more edges of the substrate increases a uniformity of a density of the plasma over the substrate.

8. The method of claim 7, wherein increasing the uniformity of the density of the plasma over the substrate increases a uniformity of a thickness of the film formed on the substrate.

9. A processing chamber comprising:
a gas distributor configured to generate a plasma within a processing volume of by ionizing a processing gas;
a substrate support configured to support a substrate within the processing volume;
a gas inlet port disposed along a first wall of the processing chamber; and
a gas supply source coupled to the gas inlet port and configured to introduce a barrier gas into the processing volume to generate a gas curtain along one or more edges of the substrate during a period overlapping with generating the plasma within the processing volume.

10. The processing chamber of claim 9, wherein the first wall of the processing chamber is opposite the gas distributor.

11. The processing chamber of claim 9, wherein the gas supply source is configured to supply the barrier gas at a flow rate based on at least one of a flow rate of the processing gas, a type of the barrier gas and a type of the processing gas.

12. The processing chamber of claim 9, wherein the barrier gas is one of helium, hydrogen, nitrogen, argon, oxygen, or nitrogen oxide.

13. The processing chamber of claim 9, wherein generating the gas curtain along the one or more edges of the substrate increases a uniformity of a density of the plasma over the substrate.

14. The processing chamber of claim 9 further comprising:
a shield disposed within the processing volume and surrounding the substrate support, the shield is configured to control a flow of the barrier gas; and
an exhaust port disposed along the first wall of the processing chamber.

15. A processing chamber comprising:
a gas distributor configured to provide a processing gas into a processing volume for generating a plasma;
a substrate support configured to support a substrate within the processing volume;
a gas inlet port disposed along a first wall of the processing chamber;
a gas supply source configured to introduce a barrier gas into the processing volume of the processing chamber to generate a gas curtain along one or more edges of the substrate during a period overlapping with generating the plasma within the processing volume;
a shield disposed within the processing volume and surrounding the substrate support, the shield is configured to control a flow of the barrier gas to form the gas curtain; and
an exhaust port disposed along the first wall of the processing chamber.

16. The processing chamber of claim 15 further comprising:
a power supply configured to generate the plasma within an interior region of the processing chamber by ionizing the processing gas.

17. The processing chamber of claim 16, wherein the substrate is positioned between the gas distributor and the first wall of the processing chamber.

18. The processing chamber of claim 15, wherein generating the gas curtain along the one or more edges of the substrate increases a uniformity of a density of the plasma over the substrate.

19. The processing chamber of claim 18, wherein increasing the uniformity of the density of the plasma over of the substrate increases a uniformity of a thickness of a film formed on the substrate.

20. The processing chamber of claim 15, wherein the gas supply source is configured to supply the barrier gas at a flow rate is based on at least one of a flow rate of the processing gas, a type of the barrier gas, and a type of the processing gas.
